(19) United States
(12) Patent Application Publication
(10) Pub. No.: US 2025/0379077 A1
(43) Pub. Date: Dec. 11, 2025

(54) SUBSTRATE SUPPORTS INCLUDING MEASUREMENT ASSEMBLIES, AND RELATED APPARATUS, METHODS, AND PROCESSING CHAMBERS

(71) Applicant: Applied Materials, Inc., Santa Clara, CA (US)

(72) Inventors: Juan Carlos ROCHA-ALVAREZ, San Carlos, CA (US); Jian LI, Fremont, CA (US)

(21) Appl. No.: 18/737,275

(22) Filed: Jun. 7, 2024

(51) Int. Cl. H01L 21/67; H01J 37/32; H01L 21/687

(52) U.S. Cl. CPC H01L 21/67253; H01J 37/32724; H01L 21/68785

(57) ABSTRACT

Embodiments of the present disclosure generally relate to substrate supports including measurement assemblies, and related apparatus, methods, and processing chambers (e.g., semiconductor processing chambers). In one or more embodiments, a substrate support for disposition in a processing chamber includes a support body including a ceramic material, and a measurement assembly embedded in the support body. The measurement assembly includes a resistor, an input wire coupled to the resistor, an input pad coupled to the input wire, and an output wire coupled to the resistor. The input wire and the output wire have a lower resistance than the resistor. The measurement assembly includes an output pad coupled to the output wire.

### BACKGROUND

### FIELD

Embodiments of the present disclosure generally relate to substrate supports including measurement assemblies, and related apparatus, methods, and processing chambers (e.g., semiconductor processing chambers).

### DESCRIPTION OF THE RELATED ART

Substrate supports in process chambers often include one or more sensors to perform measurements used for controlling the process (e.g., deposition) performed in the process chamber. For example, substrate supports often include one or more temperature sensors inside the substrate support. Positioning a sensor in the interior of the substrate support can be challenging, expensive, and/or can involve time delays. Such issues can be exacerbated when the sensor is located near the outer edge of the substrate support.

Accordingly, there is a need for improved substrate supports.

### SUMMARY

Embodiments of the present disclosure generally relate to substrate supports including measurement assemblies, and related apparatus, methods, and processing chambers (e.g., semiconductor processing chambers).

In one or more embodiments, a substrate support for disposition in a processing chamber includes a support body including a ceramic material, and a measurement assembly embedded in the support body. The measurement assembly includes a resistor, an input wire coupled to the resistor, an input pad coupled to the input wire, and an output wire coupled to the resistor. The input wire and the output wire have a lower resistance than the resistor. The measurement assembly includes an output pad coupled to the output wire.

In one or more embodiments, a substrate support for disposition in a processing chamber includes a support body including a ceramic material. The substrate support includes one or more heat elements disposed in the support body, one or more electrodes disposed in the support body, and a resistor disposed in the support body. The resistor is disposed at a first distance relative to the one or more heat elements and at a second distance relative to the one or more electrodes.

In one or more embodiments, a method of forming a substrate support includes disposing a resistor, an input pad, and an output pad in a ceramic material. The method includes sintering the ceramic material. The method includes calibrating a sensor coupled to the resistor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 depicts a schematic side view of a processing chamber having a substrate support, according to one or more embodiments.

FIGS. 2A-2C are schematic process flow views of a method of forming a substrate support, according to one or more embodiments.

FIG. 3 is a schematic partial top view of the substrate support shown in FIG. 2C, according to one or more embodiments.

FIG. 4 is a schematic partial top view of a multi-volume processing chamber, according to one or more embodiments.

FIGS. 5A-5C are schematic process flow views of a method of forming a substrate support, according to one or more embodiments.

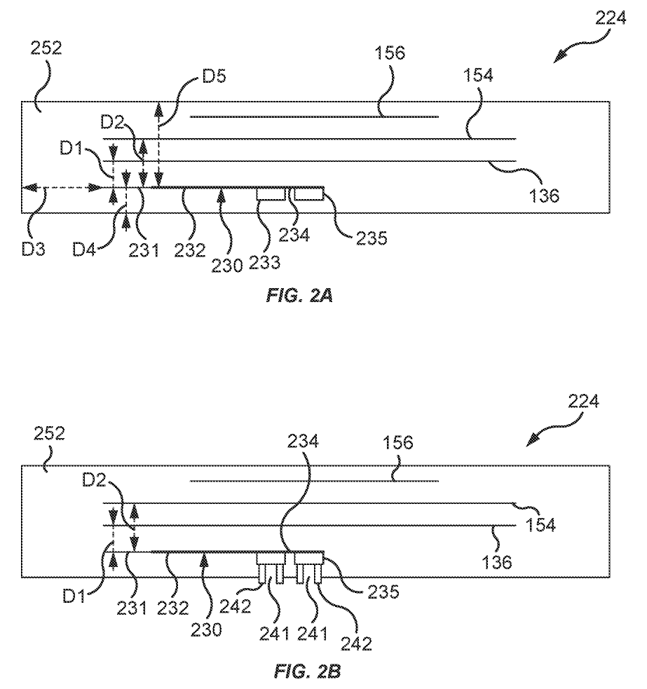

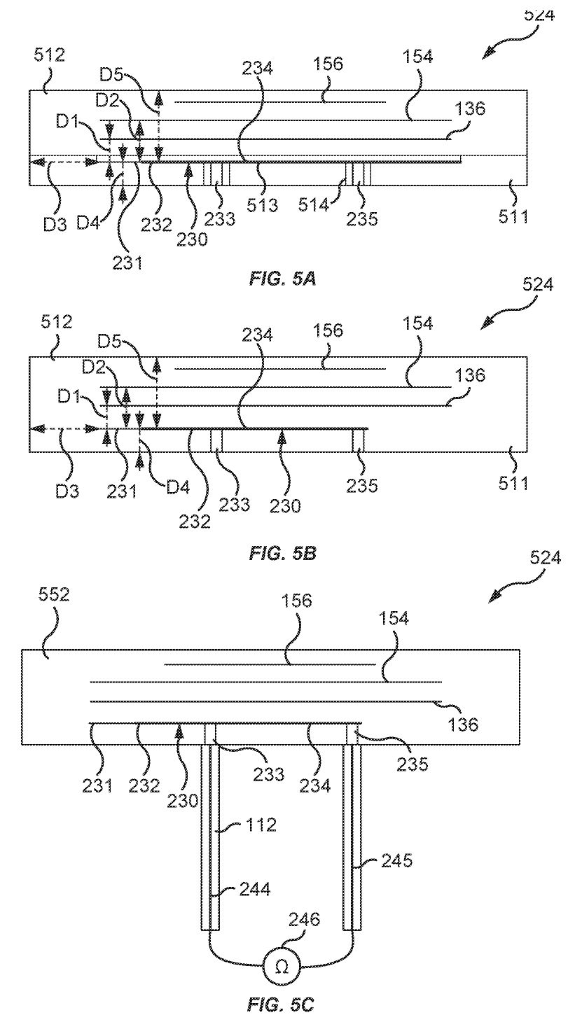

Certain figures omit cross-sectional hatching from certain components for visual clarity purposes. For example, in FIGS. 2A-2C hatching is omitted from support body 252. As another example, in FIGS. 5A-5C hatching is omitted from first plate 511, second plate 512, and support body 552.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to substrate supports including measurement assemblies, and related apparatus, methods, and processing chambers (e.g., semiconductor processing chambers). A resistor is disposed (e.g., embedded) in a support body of a substrate support. In one or more embodiments, the resistor includes a metallic coil. In one or more embodiments, the resistor is disposed in a volume of powder, and the powder is sintered to form the support body and embed the resistor in the support body. In one or more embodiments, two volumes of powder are initially sintered (e.g., partially sintered) to form two plates, a recess can be formed in at least one of the two pates, and the resistor is disposed in the recess. The two plates can be sandwiched together with the resistor therebetween, and the two plates can then be sintered to form the support body and embed the resistor in the support body.

Although the present disclosure mainly describes substrate supports (e.g., heaters) with internal sensors, the methods and apparatus can be more generally applied to other components used in process chambers, such as electrostatic chucks, showerheads, or other components that are exposed to harsh process conditions.

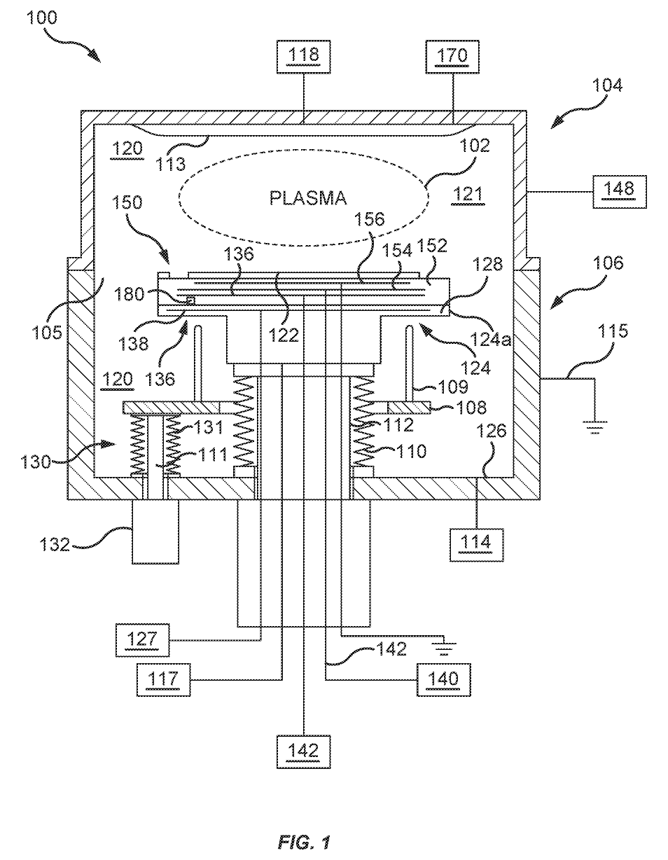

FIG. 1 depicts a schematic side view of a processing chamber 100 having a substrate support 124, according to one or more embodiments. In one or more embodiments, the processing chamber 100 is a deposition chamber (such as a plasma-enhanced deposition, e.g. plasma-enhanced CVD chamber). In one or more embodiments, the processing chamber 100 is an etching chamber. Other types of processing chambers configured for different processes can also use or be modified for use with examples of the substrate support 124 described herein.

The processing chamber 100 can be a vacuum chamber that is suitably adapted to maintain sub-atmospheric pressures within a chamber interior volume 120 during substrate processing. The processing chamber 100 includes a chamber body 106 covered by a lid 104 which encloses a processing volume 121 located in the upper portion of the chamber interior volume 120 and generally above the substrate support 124. The processing chamber 100 may also include one or more liners circumscribing various chamber components to prevent unwanted reaction between such components and the gases of the processing environment within the processing chamber 100. The chamber body 106 and lid 104 may be made of metal, such as aluminum. The chamber body 106 may be grounded via a coupling, such as a ground strap, to ground 115.

The substrate support 124 is disposed within the interior volume 120 to support and retain a substrate 122 thereon, such as a semiconductor substrate. A substrate support assembly 150 includes a substrate support 124 disposed on a hollow support shaft 112 for supporting the substrate support 124. The substrate support 124 includes a support body 152 including a ceramic material. One or more chucking electrodes 154 are disposed in the support body 152, and the one or more chucking electrodes 154 electrostatically chuck the substrate 122 to the substrate support 124.

The hollow support shaft 112 provides a conduit to provide, for example, backside gases through backside gas lines, process gases through process gas lines, fluids through fluid lines, coolant gases through coolant lines, power cabling, or the like, to the substrate support 124. In one or more embodiments, the hollow support shaft 112 is attached to a bottom surface of the chamber body 106 and the substrate support 124 is fixed in the processing chamber 100. In one or more embodiments, the hollow support shaft 112 is coupled to a lift mechanism, such as an actuator or motor, which provides vertical movement of the substrate support 124 between an upper, processing position (as shown in FIG. 1) and a lower, transfer position. A bellows assembly 110 is disposed about the hollow support shaft 112 and is coupled between the substrate support 124 and a bottom surface 126 of processing chamber 100 to provide a flexible seal that allows vertical motion of the substrate support 124 while preventing loss of vacuum from within the processing chamber 100.

The hollow support shaft 112 provides a conduit for coupling wiring or other electrical conductors between a negative pulsed DC power source 140, a bias power supply 117 to the substrate support 124. In one or more embodiments, the bias power supply 117 includes one or more RF bias power sources. In one or more, the substrate support 124 may include AC, DC, or RF bias power.

The processing chamber 100 may, or may not, include a substrate lift assembly 130. The substrate lift assembly 130 may include lift pins 109 mounted on a platform 108 connected to a shaft 111 which is coupled to a second lift mechanism 132 for raising and lowering the platform 108 and pins 109 so that the substrate 122 may be placed on or removed from the substrate support 124. The substrate support 124 includes through holes to receive the lift pins 109. A bellows assembly 131 is coupled between the substrate lift assembly 130 and the bottom surface 126 to provide a flexible seal that maintains the chamber vacuum during vertical motion of the substrate lift assembly 130. The substrate lift assembly 130 may be included entirely inside the processing chamber 100, for example within the substrate support 124.

The processing chamber 100 can include a showerhead 113 for directing process gases into the interior volume 120 of the processing chamber 100. The processing chamber 100 is coupled to and in fluid communication with a pumping system 114 that includes a throttle valve and vacuum pump which are used to exhaust the processing chamber 100. The pressure inside the processing chamber 100 may be regulated by adjusting the throttle valve and/or vacuum pump. The processing chamber 100 is also coupled to and in fluid communication with a process gas supply 118 that may supply one or more process gases to the processing chamber 100 for processing the substrate 122 disposed therein.

In operation, a plasma 102 is created in the chamber interior volume 120 to perform one or more processes. The plasma 102 may be created by coupling power from a plasma power source, e.g., RF plasma power supply 170, to a process gas via one or more electrodes (for example a coil not shown) near and exterior to the lid 104, or within the chamber interior volume 120, to ignite the process or other gas therein into a plasma 102. A bias power may be provided from the bias power supply 117 to the one or more chucking electrodes 154 within the substrate support 124 in addition to the chucking power to attract ions from the plasma 102 towards the substrate 122 to etch the exposed upper surface of the substrate 122. An electrode 156 may be embedded within the ceramic body of the substrate support 124 and connected to a separate or common power supply (e.g., the RF plasma power supply 170) or ground. The RF plasma power supply 170 may provide RF energy at a frequency of about 40MHz or greater at a desired power level to the processing chamber 100 for maintaining the plasma 102 therein. For example, the power source 142 may deliver 3,000 Watts (W) or more of high-frequency RF power, 1,000 W or more of low-frequency RF power, or both. The electrode 156 receives and/or supplies electrical power (e.g., RF current) from and/or to the processing volume 121 to generate and maintain the plasma during processing.

The substrate support 124 is disposed on the hollow support shaft 112. The substrate support 124 includes one or more heating elements 136 are embedded in the substrate support 124. The one or more heating elements 136 may be a plate, a perforated plate, a mesh, a wire screen, or any other distributed arrangement. The one or more heating elements 136 is coupled to a power source 142. The one or more heating elements 136 can heat the substrate support to a desired temperature, such as 400 °C, or another processing temperature.

A sensor 180 is disposed (e.g., embedded) in the support body 152.

The substrate support 124 can include a cooling plate assembly 128 between the support body 152 and the shaft 112. The cooling plate assembly 128 may be formed from a metal material or other suitable material. For example, the cooling plate assembly 128 may be formed from aluminum (Al). The cooling plate assembly 128 may include cooling gas channels 138 formed therein. The cooling plate assembly 128 is configured to be coupled to a cooling gas source 127, e.g., the cooling gas channels 138 may be connected to the cooling gas source 127. The cooling gas source 127 provides a cooling gas that is circulated through one or more cooling gas channels 138.

FIGS. 2A-2C are schematic process flow views of a method of forming a substrate support 224, according to one or more embodiments. The substrate support 224 can be used, for example, as a least part of the substrate support 124 shown in FIG. 1.

In FIG. 2A, a support body 252 of the substrate support 224 is formed by disposing a measurement assembly 230 in a powder, and then sintering the powder to form the support body 252 around the measurement assembly 230 to embed the measurement assembly 230 in the support body 252. The support body 252 includes a ceramic material, such as aluminum nitride (AlN). Other ceramic materials are contemplated. Other materials are contemplated for the support body 252. In one or more embodiments, the support body 252 is formed of AlN. The measurement assembly 230 includes a resistor 231, an input wire 232 coupled to the resistor 231, an input pad 233 coupled to the input wire 232, and an output wire 234 coupled to the resistor 231. The input wire 232 and the output wire 234 having a lower resistance than the resistor 231. The measurement assembly 230 includes an output pad 235 coupled to the output wire 234. The resistor 231 is encapsulated by the ceramic material of the support body 252. The resistor 231, the input wire 232, the input pad 233, the output wire 234, and the output pad 235 respectively include molybdenum. The input pad 233 and the output pad 235 are disposed radially inward of the resistor 231.

The resistor 231, the input wire 232, the input pad 233, the output wire 234, and the output pad 235 respectively have a coefficient of thermal expansion (CTE) within a difference of 10% or less relative to a CTE of the ceramic material of the support body 252. In one or more embodiments, the CTE of the resistor 231, the input wire 232, the input pad 233, the output wire 234, and/or the output pad 235 is about equal to the CTE of the ceramic material. The CTE of the resistor 231, the input wire 232, the input pad 233, the output wire 234, and/or the output pad 235 is less than 7.0 parts-per-million (ppm)/degrees Celsius (°C), such as within a range of 5.0 ppm/°C to 6.0 ppm/°C. The resistor 231, the input wire 232, the input pad 233, the output wire 234, and/or the output pad 235 respectively have a melting point above 2,000 degrees Celsius. The resistor 231 has a higher electrical resistivity than the ceramic material of the support body 252. The input wire 232, the output wire 234, the input pad 233, and the output pad 235 respectively have a lower electrical resistivity than the resistor 231.

The resistor 231 is disposed in the support body 252 at a first distance D1 relative to one or more heat elements 136 disposed in the support body 252 and at a second distance D2 relative to one or more electrodes (such as the one or more chucking electrodes 154 and/or the electrode 156) disposed in the support body 252. The first distance D1 and the second distance D2 are respectively at least 2.0 mm, such as within a range of 2.0 mm to 3.0 mm or greater. The resistor 231 is disposed at a third distance D3 relative to an outer edge of the support body 252, and at a fourth distance D4 relative to an outer surface (such as a lower surface) of the support body 252. The third distance D3 and the fourth distance D4 are respectively at least 2.0 mm, such as within a range of 2.0 mm to 3.0 mm or greater. The resistor 231 is disposed at a fifth distance D5 relative to a second outer surface (such as a substrate support surface). The fifth distance D5 is at least 2.0 mm, such as within a range of 2.0 mm to 3.0 mm or greater. In one or more embodiments, the fifth distance D5 is within a range of 20.0 mm to 25.0 mm. The sintering of FIG. 2A includes a first temperature that is greater than 1,750 degrees Celsius, such as within a range of 1,800 degrees Celsius to 2,000 degrees Celsius, or higher.

In FIG. 2B, one or more openings 241 are formed in the ceramic material of the support body 252. One or more inserts 242 are disposed respectively in the one or more openings 241. In one or more embodiments, the one or more inserts 242 include gold, nickel, and/or an alloy of iron-nickel-cobalt. In one or more embodiments, the one or more inserts 242 have a higher CTE than the ceramic material of the support body 252. The inserts 242 can be threaded, such as threaded into the support body 252 and/or threaded over one or more conduits 243 shown in FIG. 2C.

In FIG. 2C, the one or more conduits 243 are coupled to the input pad 233 and the output pad 235. The one or more conduits 243 are disposed respectively in the inserts 242 and then are brazed to the input and output pads 233, 235 and/or the support body 252. The material of the one or more inserts 242 are disposed between the support body 252 and the respective one or more conduits 243. The material has an intermediate CTE that is between the CTE of the ceramic material and the CTE of the one or more conduits 243. The one or more insets 242 can transition the CTE of the support body 252 to the CTE of the one or more conduits 243 while providing mechanical strength. In one or more embodiments, the one or more inserts 242 include a buffer material, such as copper. In one or more embodiments, the buffer material includes copper and the one or more conduits 243 include nickel. In one or more embodiments, the CTE of the ceramic material is within a range of 5.0 ppm/°C to 6.0 ppm/°C, and the inserts 242 and/or the one or more conduits 243 have a CTE within a range of 13.0 ppm/°C to 14.0 ppm/°C. A first lead line 244 is disposed into a first conduit 243 and a second lead line 245 is disposed into a second conduit 243. The brazing of the one or more conduits 243 couples the first lead line 244 to the input pad 233 and the second lead line 245 to the output pad 235. The present disclosure contemplates that the input pad 233 and the output pad 235 can couple to temperature measurement circuit(s).

A measurement device 246 (such as an Ohmmeter) is coupled to the first lead line 244 and the second lead line 245. The measurement device 246 measures a resistance of the resistor 231. Using one or more factors (e.g., a predetermined factor), the measured resistance can be correlated to (e.g., to interpolate) a temperature of a region of the substrate support 224 (and/or a substrate supported thereon). The one or more factors can be represented in a profile as measured resistance versus measured temperature. As an example, an increase in the measured resistance of the resistor 231 can indicate an increased temperature of the resistor 231. As such, the measurement assembly 230 is a temperature measurement assembly. The present disclosure contemplates that the subject matter described herein can be used to measure parameters other than temperature (such as voltage, chucking force, and/or current flow). The resistor 231 has a resistivity that is at least 4.0 x 10⁻⁸ meters-Ohms (m-Ω) at room temperature. In one or more embodiments, the resistivity is about 5.0 x 10⁻⁸ meters-Ohms (m-Ω) or higher at room temperature.

Prior to the brazing of FIG. 2C, the shaft 112 is bonded to the support body 252 of the substrate support 224. The bonding includes a second temperature that is within a range of 1,300 degrees Celsius to 1,500 degrees Celsius, such as within a range of 1,300 degrees Celsius to 1,400 degrees Celsius. The brazing includes a third temperature that is 1,000 degrees Celsius or less, such as within a range of 800 degrees Celsius to 1,000 degrees Celsius.

After the substrate support 224 is formed at FIG. 2C, a temperature sensor 251 (such as a pyrometer (e.g, an optical pyrometer)) can be oriented to measure a temperature along a region of the substrate support 224 that is aligned (e.g., vertically) with the resistor 231. The temperature measured by the temperature sensor 251 can be compared to the temperature measured by the resistor 231 and the measurement device 246 to adjust (e.g., calibrate) the temperature measured by the resistor 231 and the measurement device 246. As an example, a correction factor can be applied to the temperature measured by the resistor 231 and the measurement device 246 to more closely match the temperature measured by the temperature sensor 251.

Prior to temperature measurement using the resistor 231, the temperature sensor 251 can measure temperatures in order to determine the one or more factors that are correlated to the measured resistance to measure temperature using the resistor 231. Other methods are contemplated for determining the one or more factors that are subsequently used to correlate measured resistance to a measured temperature.

The temperature measurements of the resistor 231 can be used to control heating and/or cooling of the substrate support 224. For example, the temperature measurements can be supplied to a feedback loop that controls the supply of power to the one or more heating elements 136 and/or the one or more cooling gas channels 138.

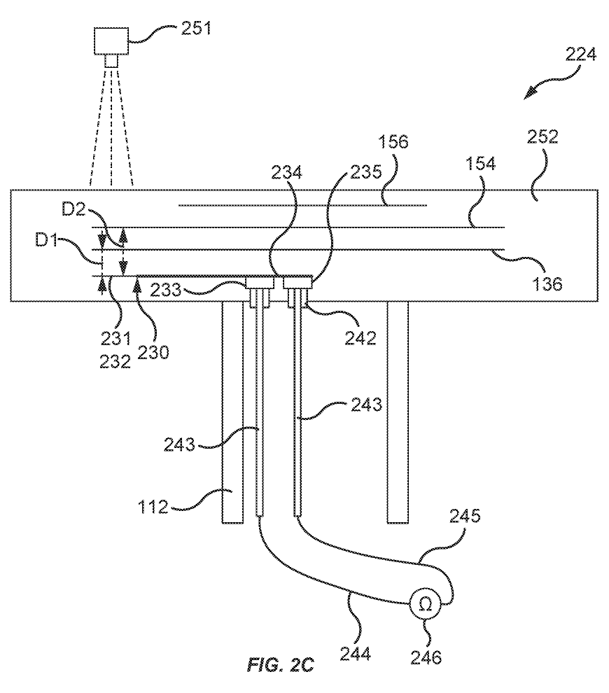

FIG. 3 is a schematic partial top view of the substrate support 224 shown in FIG. 2C, according to one or more embodiments. In one or more embodiments, the resistor 231 includes a metal coil. Other resistors are contemplated.

As shown in FIG. 3, the substrate support 224 can include multiple measurement assemblies 230. The respective resistors 231 can be disposed at different distances within the support body 252, and/or at different radial positions in the support body 252. As an example, the resistors 231 can be positioned to measure temperature at an inner radial zone and an outer radial zone of the substrate support 224.

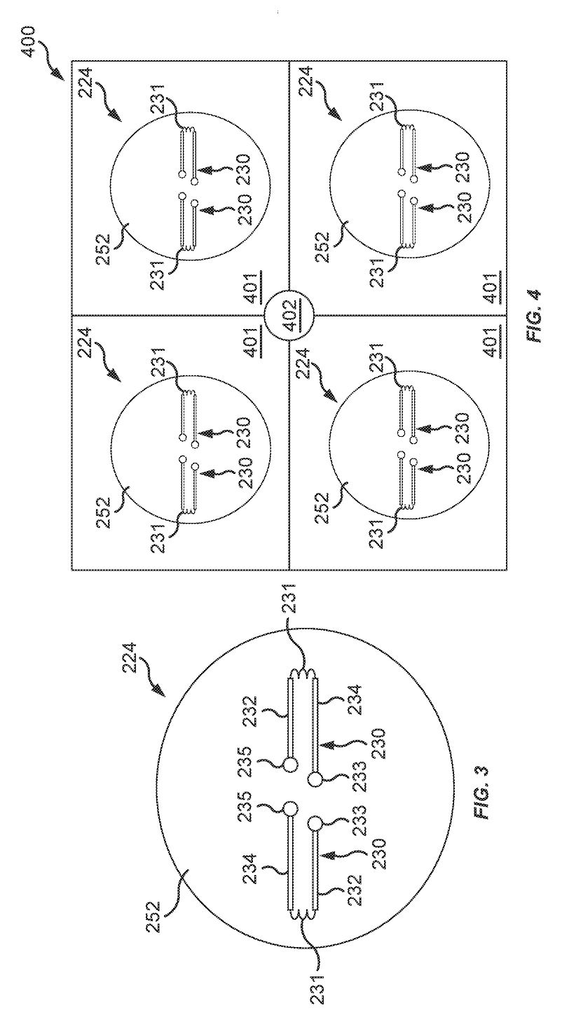

FIG. 4 is a schematic partial top view of a multi-volume processing chamber 400, according to one or more embodiments. The multi-volume processing chamber 400 includes a plurality of processing volumes 401 (four are shown in FIG. 4). At least one substrate support 224 can be disposed in each processing volume 401. The processing chamber 400 can include a common exhaust 402 for exhausting gases from the plurality of processing volumes 401.

FIGS. 5A-5C are schematic process flow views of a method of forming a substrate support 524, according to one or more embodiments. The 136, the 154, and the 156 can be disposed in the partially sintered second plate 512. The substrate support 524 can be used, for example, as a least part of the substrate support 124 shown in FIG. 1. The method and/or the substrate support 524 can be similar to the method and/or the substrate support 224 shown in FIGS. 2A-2C, and can include one or more aspects, features, components, operations, and/or properties thereof.

In FIG. 5A, a first plate 511 and a second plate 512 have been initially sintered (e.g., partially sintered). The resistor 231, the input pad 233, and the output pad 235 are disposed in one or more openings 513, 514 formed in the first plate 511. In one or more embodiments, the resistor 231, the input wire 232, and the output wire 234 are disposed in a recess 513 formed in the initially sintered first plate 511, and the input pad 233 and the output pad 235 are disposed in holes 514 formed in the initially sintered first plate 511. The initially sintered second plate 512 is positioned to cover the resistor 231, the input wire 232, the output wire 234, the input pad 233, and the output pad 235. The recess 513 can define a cavity when the resistor 231 is sandwiched between the first plate 511 and the second plate 512.

In FIG. 5B, the first plate 511 and the second plate 512 are sintered (e.g., completely sintered) to form a support body 552. The sintering closes off the one or more openings 513, 514 to encapsulate the resistor 231, the input wire 232, and the output wire 234. The sintering encapsulates at least three sides of the input pad 233 and the output pad 235 while leaving bottom surfaces thereof exposed. The present disclosure also contemplates that the input pad 233 and the output pad 235 can be disposed in the recess 513 shown in FIG. 5A, the holes 514 can be omitted from the initially sintered first plate 511, and after the sintering of FIG. 5B openings similar to openings 241 can be formed in the support body 552.

In FIG. 5C, the shaft 112 is bonded (e.g., diffusion bonded) to the support body 552. The one or more lead lines 244, 245 are embedded in a wall of the shaft 112. The one or more lead lines 244, 245 extend through the wall of the shaft 112. For example the one or more lead lines 244, 245 can be sintered in the shaft 112 prior to the bonding. The bonding can couple the first lead line 244 to the input pad 233 and the second lead line 245 to the output pad 235.

The resistor 231 (e.g., a sensor) and the measurement device 246 can be used to control heat provided to the substrate support 224, 524. The shaft 112 can be used to lift and/or rotate the substrate support 224, 524. The input pad 233 and the output pad 235 respectively have a width that is narrower than a thickness of the shaft 112.

Benefits of the present disclosure include efficient, quick, and inexpensive fabrication of substrate supports with embedded measurement assemblies. For example, the machining and/or bonding of plates is reduced or eliminated. As another example, the number of manufacturing iterations is reduced or eliminated. Benefits also include accurate measurements, and accurate adjustment and calibration of measurements (such as temperature measurements). Benefits also include enhanced surface flatness, and heating efficiency (such as energy transmission).

It is contemplated that one or more aspects disclosed herein may be combined. As an example, one or more aspects, features, components, operations and/or properties of the processing chamber 100, the substrate support 124, the substrate support 224, the method shown in FIGS. 2A-2C, the multi-volume processing chamber 400, the substrate support 524, and/or the method shown in FIGS. 5A-5C may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof.

What is claimed is:

1. A substrate support for disposition in a processing chamber, comprising:
a support body comprising a ceramic material; and
a measurement assembly embedded in the support body, the measurement assembly comprising:
a resistor,
an input wire coupled to the resistor,
an input pad coupled to the input wire,
an output wire coupled to the resistor, the input wire and the output wire having a lower resistance than the resistor, and
an output pad coupled to the output wire.

2. The substrate support of claim 1, wherein the resistor includes a metal coil encapsulated by the ceramic material of the support body, the metal coil comprising molybdenum.

3. The substrate support of claim 2, wherein the metal coil has a coefficient of thermal expansion less than 7.0 ppm/°C.

4. The substrate support of claim 2, wherein the metal coil has a coefficient of thermal expansion within a difference of 10% or less relative to a coefficient of thermal expansion of the ceramic material.

5. The substrate support of claim 1, wherein the input pad and the output pad are disposed radially inward of the resistor.

6. The substrate support of claim 1, further comprising one or more conduits coupled to the input pad and the output pad.

7. The substrate support of claim 6, further comprising a buffer material disposed between the support body and the one or more respective conduits.

8. The substrate support of claim 7, wherein the buffer material has an intermediate coefficient of thermal expansion that is between a coefficient of thermal expansion of the ceramic material and a coefficient of thermal expansion of the one or more conduits.

9. The substrate support of claim 7, wherein the buffer material comprises copper, and the one or more conduits comprise nickel.

10. A substrate support for disposition in a processing chamber, comprising:
a support body comprising a ceramic material;
one or more heat elements disposed in the support body;
one or more electrodes disposed in the support body; and
a resistor disposed in the support body at a first distance relative to the one or more heat elements and at a second distance relative to the one or more electrodes.

11. The substrate support of claim 10, wherein the first distance and the second distance are respectively at least 2.0 mm.

12. The substrate support of claim 10, further comprising
a shaft coupled to the support body;
an input pad disposed in the support body;
an output pad disposed in the support body;
a first lead line extending through a wall of the shaft, the first lead line coupled to the input pad; and
a second lead line extending through the wall of the shaft, the second lead line coupled to the output pad.

13. The substrate support of claim 10, wherein the resistor includes a metal coil encapsulated by the ceramic material of the support body, the metal coil comprising molybdenum.

14. The substrate support of claim 13, wherein the metal coil has a coefficient of thermal expansion within a difference of 10% or less relative to a coefficient of thermal expansion of the ceramic material.

15. A method of forming a substrate support, comprising:
disposing a resistor, an input pad, and an output pad in a ceramic material;
sintering the ceramic material; and
calibrating a sensor coupled to the resistor.

16. The method of claim 15, further comprising, prior to the sintering:
initially sintering the ceramic material into a first plate and a second plate, wherein the disposing comprises:
disposing the resistor, the input pad, and the output pad in one or more openings formed in the first plate, and
positioning the second plate to cover the resistor, the input pad, and the output pad.

17. The method of claim 15, further comprising:
forming one or more openings in the ceramic material to expose the input pad and the output pad; and
brazing one or more lead lines to the input pad and the output pad, wherein the sintering includes a first temperature that is greater than 1,750 degrees Celsius, and the brazing includes a second temperature that is 1,000 degrees Celsius or less.

18. The method of claim 15, further comprising bonding one or more lead lines to the input pad and the output pad, wherein the sintering includes a first temperature that is greater than 1,750 degrees Celsius, and the bonding includes a second temperature that is within a range of 1,300 degrees Celsius to 1,500 degrees Celsius.

19. The method of claim 15, wherein the sintering encapsulates the resistor by the ceramic material, and the resistor includes a metal coil encapsulated by the ceramic material.

20. The method of claim 19, wherein the metal coil comprises molybdenum.
